(19) United States
(12) Patent Application Publication
(10) Pub. No.: US 2026/0136588 A1
(43) Pub. Date: May 14, 2026

(54) LDMOS AND METHOD OF MANUFACTURING THE SAME

(71) Applicant: UNITED MICROELECTRONICS CORP., Hsin-Chu City (TW)

(72) Inventors: Kuan-Liang Liu, Hsinchu County (TW); Chien-Hung Chen, Taipei City (TW)

(73) Assignee: UNITED MICROELECTRONICS CORP., Hsin-Chu City (TW)

(21) Appl. No.: 18/979,553

(22) Filed: Dec. 12, 2024

(30) Foreign Application Priority Data
Nov. 11, 2024 (TW) 113143160

(51) Int. Cl. H10D 30/65; H10D 30/01; H10D 62/10

(52) U.S. Cl. CPC H10D 30/65; H10D 30/0281; H10D 62/116

(57) ABSTRACT

A LDMOS is provided in the present invention, including multiple fins spaced apart, wherein each fin has a recess region, a shallow trench isolation in those recess regions forms a thick oxide layer, a gate crosses over those fins, wherein the thick oxide layer is close to one side of the gate and partially overlaps the gate, and a source and a drain respectively at two sides of the gate in each fin, wherein the thick oxide layer extends outside the gate to the drains.

### BACKGROUND OF THE INVENTION

### 1. Field of the Invention

The present invention generally relates to a laterally diffused metal oxide semiconductor (LDMOS), and more specifically, to a LDMOS having different fin heights and method of manufacturing the same.

### 2. Description of the Prior Art

Laterally diffused metal oxide semiconductor (LDMOS) is a power field effect transistor, which is mostly used in high-voltage and high-power radio frequency (RF) applications, such as power amplifier used in mobile communication cell sites, which can maintain stable operation and reliability under extremely high breakdown voltage. The characteristic of LDMOS is that there is a thick oxide layer padding under the gate near the drain terminal, such as a field oxide (FOX) or a shallow trench isolation (STI), to prevent this area from being easily punched through due to the concentration of electric field on the surface of drift region at channel end. Furthermore, by controlling the doping concentration on both sides of the lateral PN junction and the vertical PN junction in LDMOS and the thickness of the drift region, the drift region can be completely depleted before the lateral junction reaches critical breakdown voltage, thereby reducing the surface electric field (RESURF) and greatly increasing the breakdown voltage of the drain terminal.

However, if a LDMOS is to be made into a type of fin field effect transistor (FinFET), it will encounter problems in forming the aforementioned thick oxide layer, because the thick oxide layer is usually formed by thermal oxidation of reacting the silicon-based surface of the substrate with oxygen, and the fin-shaped structure has more boundaries and corners than a flat surface, and the stress distribution therein is also more complex. These factors make it very difficult to form a thick oxide layer with uniform thickness on the fin-shaped structure. Therefore, those skilled in the art have to improve the structure and process of current LDMOS, in hope of solving the aforementioned problems.

### SUMMARY OF THE INVENTION

In view of the aforementioned problems encountered in conventional skill, the present invention hereby proposes a novel laterally diffused metal oxide semiconductor (LDMOS) structure, which is characterized by reducing the height of the fins in a thick oxide layer region to achieve the purpose of forming the thick oxide layer through a deposition process. The thick oxide layer formed by this method has an uniform thickness, meeting the requirement of high-voltage or high-power field effect transistors, and the thickness of the thick oxide layer can be simply modified by changing the height of the fins and the thickness of the deposition during the process, makes it easier to produce LDMOS devices with different on-resistances (RDS(on)) and breakdown voltages (BVD) in order to cope with different applications of the LDMOS devices.

One aspect of the present invention is to provide a LDMOS, including: a substrate with a plurality of fins spaced apart in a first direction and extending in a second direction, wherein each fin is provided with a recessed region; a shallow trench isolation surrounding the fins, wherein the shallow trench isolation located on the recessed regions forms a thick oxide layer; a gate extending over the fins in the first direction, and two sides of the gate in the second direction are a first side and a second side respectively, wherein the thick oxide layer is close to the second side, and the gate partially overlaps the thick oxide layer on each of the fins in a direction vertical to the substrate; and a source and a drain at the first side and the second side respectively in each of the fins, wherein the thick oxide layer extends from the second side of the gate to the drain.

Another aspect of the present invention is to provide a method of manufacturing a LDMOS, including: providing a substrate with a plurality of fins spaced apart in a first direction and extending in a second direction; performing a first photolithography process to reduce a height of the fins in a recessed region; forming a dielectric layer on the fins, wherein the dielectric layer on the fins in the recessed region forms a thick oxide layer; performing a second photolithography process to reduce a height of the dielectric layer not located in the recessed region, so that the dielectric layer becomes a shallow trench isolation, and the fins not located in the recessed region protrude from the shallow trench isolation; forming a gate extending over the fins in the first direction, wherein both sides of the gate in the second direction are a first side and a second side respectively, wherein the thick oxide layer is close to the second side, and the gate partially overlaps the thick oxide layer on each of the fins in a direction vertical to the substrate; and forming a source and a drain respectively at the first side and the second side in each of the fins.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 is a layout diagram of a LDMOS in accordance with one embodiment of present invention;

FIG. 2 is a schematic cross-sectional view of a LDMOS taken along a section line X-X′ in accordance with one embodiment of present invention;

FIG. 3 is a schematic cross-sectional view of a LDMOS taken along section lines Y1-Y1′, Y2-Y2′, Y3-Y3′ in accordance with one embodiment of present invention;

FIG. 4 is a complete cross-sectional view of the LDMOS in accordance with one embodiment of present invention;

FIG. 5 is a schematic cross-sectional view of a LDMOS with metal gate in accordance with another embodiment of present invention; and

FIGS. 6-11 are cross-sectional views illustrating a process flow of manufacturing a LDMOS with metal gate in accordance with one embodiment of present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). In addition, spatially relative terms (e.g., “beneath,” “below,” “lower,” “above,” “upper” and the like) may be used herein for ease of description to describe one element or a relationship between a feature and another element or feature as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term “based on” may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein in the description of the invention, the “N” and “P” designations, as in “N type” and “P type”, are used in the common manner to designate donor and acceptor type impurities which promote electron and hole type carriers respectively as the majority carriers. The “++” symbol, when used as a suffix with an impurity type should be interpreted to mean that the doping concentration of that impurity is heavier than the doping associated with just the letter identifying the impurity type without the “+” suffix. Conversely, the “−” symbol, when used as a suffix with an impurity type should be interpreted that the doping concentration of that impurity is lighter than the doping associated with just the letter identifying the impurity type without the “−” suffix.

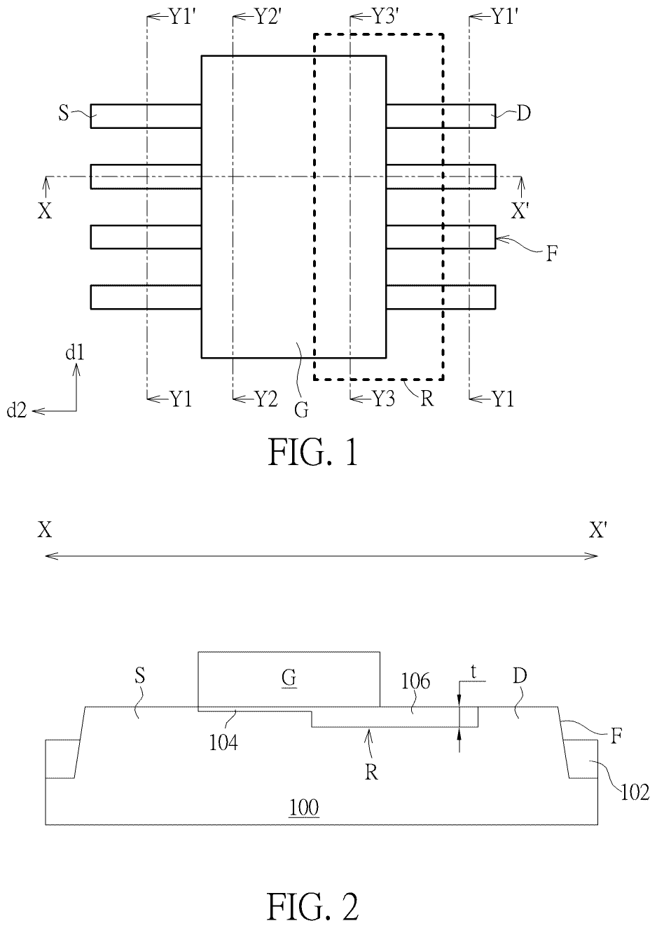

First, please refer to FIG. 1, which is a layout diagram of a laterally diffused metal oxide semiconductor (referred hereinafter as LDMOS) according to an embodiment of the present invention. As shown in the figure, the LDMOS of the present invention is generally composed of a plurality of fins F and a gate G. The fins F are arranged in parallel and spaced apart in a first direction d1, with their longitudinal axes extending in a second direction d2. The second direction d2 is preferably perpendicular to the first direction d1. The gate G extends over the fins F in the first direction d1, and the fins F are exposed from both sides of the gate G in the second direction d2, wherein the fins F exposed from one side serve as the source of the LDMOS and the fin F exposed from the other side serves as the drain D of the LDMOS. In the embodiment of the present invention, the LDMOS is provided with a recessed region R on the side close to the drain D. The recessed region R is the area where the thick oxide layer required for the LDMOS of the present invention to be formed. The thick oxide layer may be a shallow trench isolation (STI). The coverage of the recessed region R may include the overlapping portion of the gate G and the fins F at the drain side and parts of the fins F extending from this side, which is the so-called lateral diffusion region. In following embodiments, the structure and components of the LDMOS of the present invention will be explained by three cross-sections taken along the section lines X-X′, Y1-Y1′, Y2-Y2′ and Y3-Y3′ respectively shown in the figure, wherein the cross-section taken along the section line X-X′ covers the LDMOS structure in a longitudinal direction of the fins F, the cross-section taken along the section line Y1-Y1′ includes the fins F generally not covered by the gate G, and the cross-section Y3-Y3′ covers the structure where the aforementioned thick oxide layer to be formed.

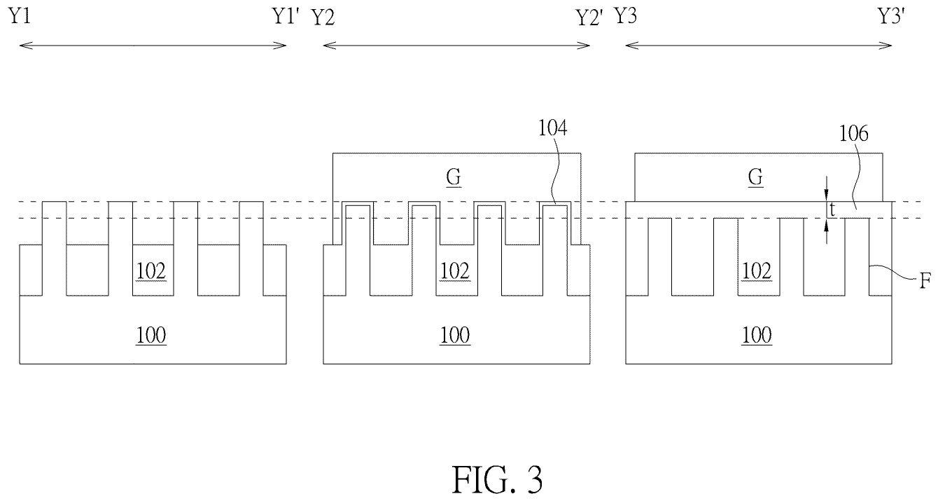

Please refer to FIG. 2, which is a schematic cross-sectional view of the aforementioned LDMOS device taken along the section line X-X′ according to an embodiment of the present invention. It should be noted that this figure shows only the appearance of the fin F and the gate G components and the relative positions therebetween. Various doped regions provided in the device will be explained in subsequent figures.

As shown in FIG. 2, the LDMOS of the present invention includes a substrate 100 as the basis for the components to be formed thereon. The material of the substrate 100 is preferably a silicon substrate, such as a P-type doped (P-) silicon substrate, but other silicon-based substrates can also be used, such as silicon-on-insulator (SOI), or a substrate of other doping types, which is not limited thereto. The substrate 100 is provided with a fin F protruding upwardly. The fin is surrounded by a shallow trench isolation (STI) 102, and the portion exposed from the STI 102 serves as active areas of the device. The material of the STI 102 can be silicon oxide, which can define and isolate different fins F. A gate G is disposed above the fin F, and the fin F exposed from both sides of the gate G are the source S and the drain D of the device, respectively. There is also a gate oxide layer 104 between the gate G and the fin F for isolation, with material like silicon oxide (ex. in the case of a polysilicon gate) or a high-k material (in the case of a metal gate). In this embodiment, the material of the gate G may be polysilicon.

It should be noted that in the embodiment of the present invention, the fin F has a recessed region R, which is located at the side close to drain D and partially overlaps the gate G in the vertical direction. A thick oxide layer 106 is formed in the recessed region R, which may be formed by parts of the STI 102, but with a height higher than the surrounding STI 102. One side of the thick oxide layer 106 overlaps the gate G in the vertical direction, and the other side extends out of the gate G and is connected with the drain D. The portion where the thick oxide layer 106 overlaps the gate G is also connected with the gate oxide layer 104 close to the source S, and both of them serve collectively as an insulating layer between the gate G and the substrate 100. It can be seen from the figure that, due to the existence of thick oxide layer 106 extending out of the gate G, the distance between drain D and gate G will be greater than the distance between the source S and the gate G, which helps to improve the high voltage endurance of the LDMOS devices, thereby improving power performance and reliability of the devices. Furthermore, the thick oxide layer 106 has a thickness t in the vertical direction, which is greater than the thickness of the adjacent gate oxide layer 104 in the vertical direction. Since in the present invention, the thick oxide layer 106 is formed due to the existence of the recessed region R, its thickness t is preferably greater than or equal to the depth of the recessed region R, which will be further described in following process embodiments. The existence of thick oxide layer 106 can avoid the breakdown of LDMOS device due to the concentration of electric field on the surface of drift region at channel end.

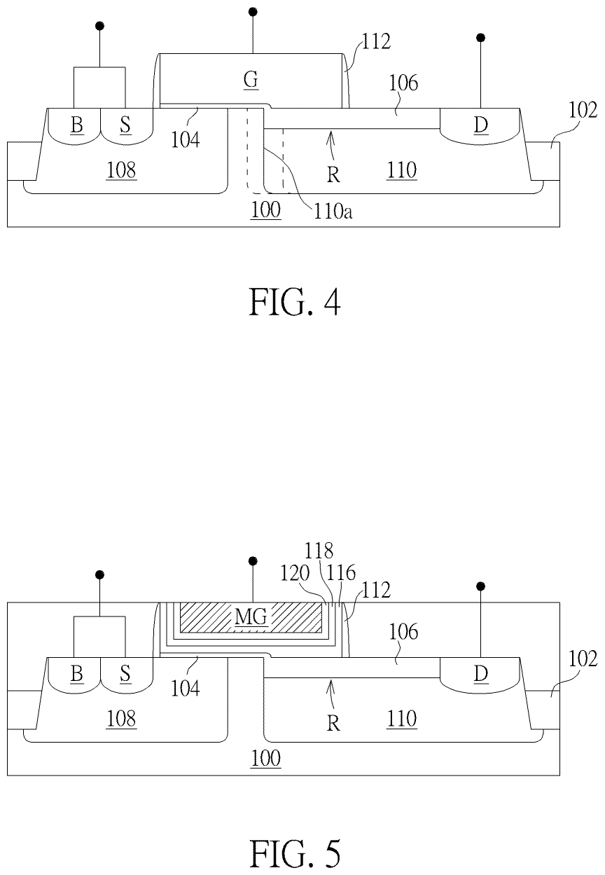

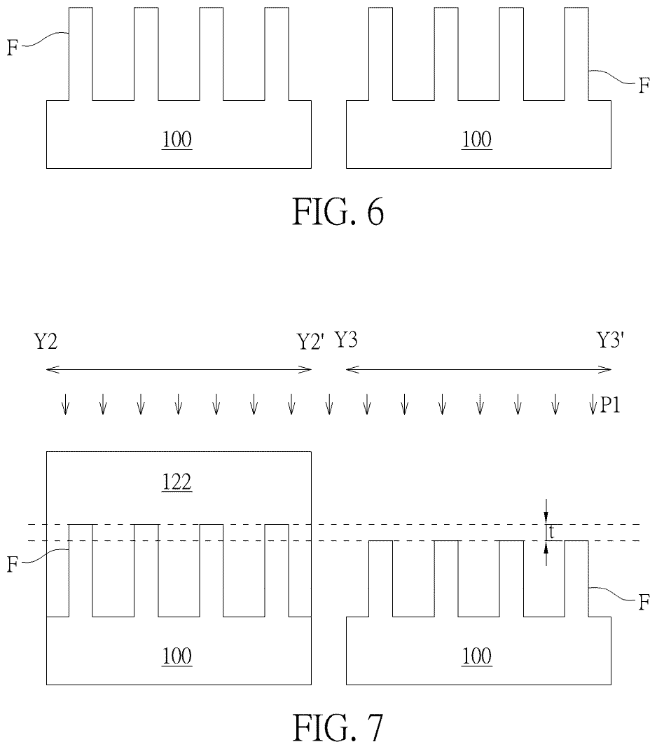

Next, please refer to FIG. 3, which shows the cross-sections of a LDMOS structure taken along the section lines Y1-Y1′, Y2-Y2′ and Y3-Y3′ of FIG. 1 respectively from left to right. As shown in the figure, the fins F protrude upwardly from the substrate 100 beyond the surrounding STIs 102 to form active areas. In the embodiment of the present invention, it should be noted that the height of fins F in the cross-section Y3-Y3′ is lower than the height of fins F in the cross-section Y1-Y1′ and the cross-section Y2-Y2′, which is exactly the position of the aforementioned recessed region R. The STI 102 located above the height of the lower fin F (cross-section Y3-Y3′) functions as the thick oxide layer 106 of the LDMOS device, which can be connected with the STI 102 surrounding the fins F below, and the two oxide-based structures can be regarded as the same dielectric structure. The thick oxide layer 106 overlapping the gate G can be regarded as a field plate, which makes the electric field on the surface of a depletion region of the device more dispersed, beneficial to increase the width of the depletion region. In another aspect, the oxide layer located above the general fins F (cross section Y2-Y2′) is the gate oxide layer 104, which is conformally formed on the exposed surface of the fins F and is in contact with the thick oxide layer 106 in the cross section Y3-Y3′ (see FIG. 2). The thickness of the thick oxide layer 106 is t, which may be greater than or equal to the depth of the recessed region R. Depending on the process used, the height of the thick oxide layer 106 may be less than, equal to, or greater than the height of the adjacent gate oxide layer 104, but is not limited thereto. For example, in the embodiment of FIG. 3, the height of thick oxide layer 106 is equal to the height of gate oxide layer 104. In the embodiment of FIG. 4, the height of thick oxide layer 106 is lower than the height of gate oxide layer 104. It can also be seen from the figure that the gate G located above the thick oxide layer 106 (i.e., on the recessed region R) does not extend downwardly into the spaces between the fins F to form a three-dimensional channel structure.

Next, please refer to FIG. 4, which is a schematic cross-sectional view of a complete LDMOS according to an embodiment of the present invention. In addition to the components and features described in the embodiments above, the LDMOS structure of the present invention also includes a P-type well (P-well) 108 and an N-type drift region 110, which are located on both sides of the gate G respectively. More specifically, the P-well 108 is located in the fin F at the side of the gate G close to the source S, which can partially overlap the gate in the vertical direction and extend horizontally to the STI outside of the fin F. The P-well 108 may be formed by a P-type doping process on this part, such as doping with dopants like boron (B) with a doping concentration higher than that of the P-type substrate 100. The function of P-well 108 is to help control the current flow more effectively in the channel of N-type LDMOS device, avoiding interference between different components and adjusting the threshold voltage of the NMOS.

In another aspect, the N-type drift region 110 is located in the fin F at the side of the gate G close to the drain D, which can overlap with parts of the gate G in the vertical direction and extend horizontally to the STI outside of the fin F, with its extension range larger than the aforementioned P-well 108 to lengthen the channel between the gate G and the drain D. It should be noted that, although the boundary 110a of the N-type drift region 110 in FIG. 4 is located between the gate oxide layer 104 and the thick oxide layer 106, in some embodiments, the boundary 110a of the N-type drift region 110 may be located below the gate oxide layer 104 or below the thick oxide layer 106, as shown by the dotted line in the figure, but is not limited thereto. In some embodiments, the N-type drift region 110 may be connected with the P-well 108. The N-type drift region 110 may be formed by a lightly doping (N−) process on the region, such as doping with dopants like phosphorus (P) and arsenic (As). In an embodiment, the N-type drift region 110 can form lateral and vertical PN junctions with the connected P-type substrate 100 and/or P-well 108. In this way, the N-type drift region 110 can be completely depleted during high-pressure operation before the lateral PN junction reaches its threshold breakdown voltage, reducing the surface electric field (RESURF) and greatly increasing the breakdown voltage of the drain terminal.

Refer still to FIG. 4. The drain D and source S of the LDMOS are formed on the aforementioned N-type drift region 110 and P-well 108 respectively, wherein the drain D and the gate G are isolated by a thick oxide layer 106, increasing the distance between the drain D and the gate G, while the source S is connected with the other side of the gate G (or is separated by a distance of a spacer 112). Both the drain D and the source S may be heavily N-type doped regions (N+), with their doping concentrations greater than that of drift region 110 which is also N-type doped. The source S is an input terminal for current, while the drain D is an output terminal for the current. In addition, in the embodiment of the present invention, a base (bulk) B is also provided on the fin F outside of the source S, which is also formed in the P-well 108 and can be connected with the source S. In some embodiments, the base B and the source S may also be separated by an isolation structure (such as a shallow trench isolation). The base B may be a heavily P-type doped region (P+) whose doping concentration is greater than that of the P-well 108 which is also P-type doped, to serve as a pick-up terminal of the P-well 108. Furthermore, in some embodiments, in order to increase the carrier mobility in the channel, the aforementioned drain D, source S and base B can be formed on a strained silicon structure, such as N-type drain D and source S formed on silicon phosphide (SiP) epitaxial crystal with tensile stress and the P-type base B formed on silicon germanium (SiGe) epitaxial crystal with compressive stress. In addition, in order to reduce contact resistance, an additional metal silicide structure (silicide), such as cobalt silicide (CoSi) or nickel silicide (NiSi), can be formed on the drain D, source S, and the base B. During operation, the drain D is connected to the operating voltage (V_{DD}) of the device. The source S and the base B are collectively connected to a reference voltage (V_{SS}), such as ground voltage (GND), with a potential between 0 and V_{DD}. The gate G is connected, but not limited, with a supply voltage (V_{CC}) of the circuit.

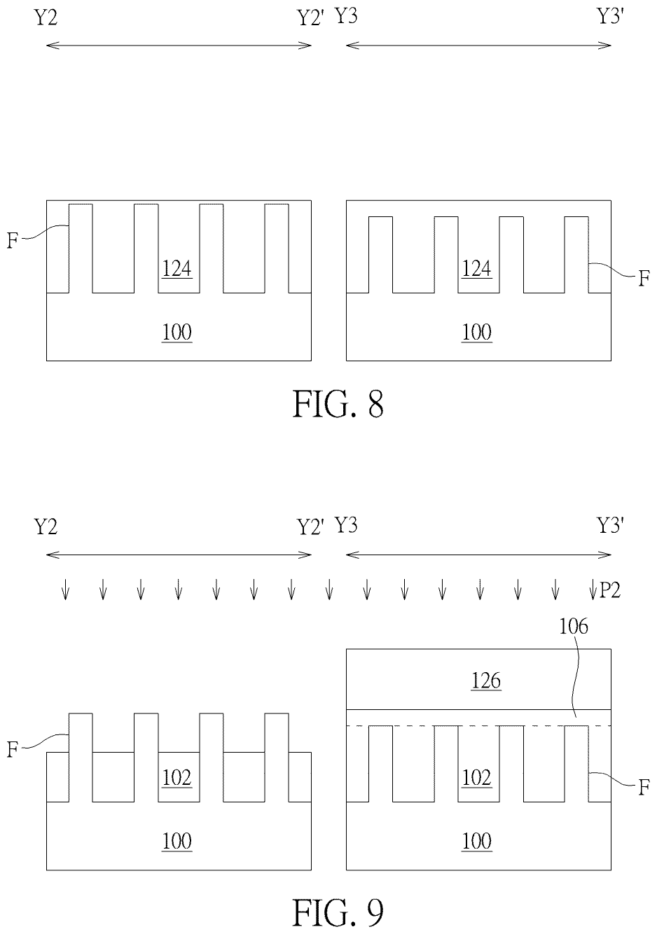

Please refer now to FIG. 5, which is a schematic cross-sectional view of a LDMOS according to another embodiment of the present invention. Different from the polysilicon gate G in previous embodiment, the LDMOS structure of the present invention can also be used in the design of metal gates. As shown in FIG. 5, the original polysilicon gate G in the LDMOS structure may be replaced with a metal gate using a replacement metal gate (RMG) process, which can include layer structures like an interfacial layer 116, a high-k layer 118, a barrier layer 120 and a filling metal MG in sequence. Among them, the interfacial layer 116, the high-k layer 118 and the barrier layer 120 are preferably formed in a conformal manner on the surface of the gate trench, and the filling metal MG fills the remaining trench space. In the embodiment, the material of the interfacial layer 116 may be silicon oxide, which helps to improve the interface quality between the metal gate and surrounding components and reduce defect density. The material of high-k layer 118 may be hafnium oxide (HfO₂), which can provide higher capacitance and improve the switching speed and performance of the device. In addition to the effect of blocking the diffusion of the filling metal, the barrier layer 120 can also function as a work function layer of the device to adjust the work function of the metal gate, achieving precise control of the threshold voltage for the device. Depending on different types and applications of the field effect transistor, the material of barrier layer 120 may be metal nitride, including tantalum nitride, molybdenum nitride, tungsten nitride, tantalum carbide, tantalum nitride carbide, titanium aluminum nitride or a combination thereof. It may also be, but not limited to, a multilayer structure. The filling metal MG is the main contact part between the metal gate and the external circuit, which can reduce the contact resistance and improve the strength of overall gate structure, with a material like tungsten (W).

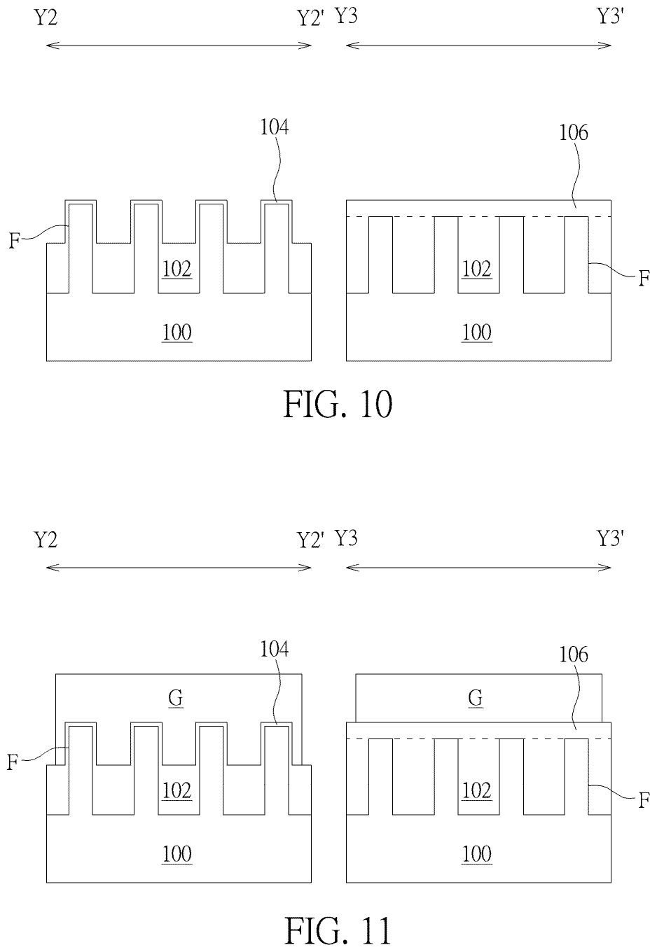

After describing the aforementioned LDMOS structure of the present invention, the following embodiments will illustrate a process of manufacturing the LDMOS of the present invention with reference to FIGS. 6-11 sequentially. These drawings will take the cross-section Y2-Y2′ (the overlapping portion of the general gate G and the fins F) and the cross-section Y3-Y3′ (the overlapping portion of the gate G and the fin F where the thick oxide layer to be formed) as examples to explain the evolution and formation of the fins F and the thick oxide layer 106 spanned by the gate G in the LDMOS of the present invention during the manufacturing process. It should be noted that the manufacturing processes of various doped regions mentioned above will be omitted in these figures to avoid obscuring the focus of the present invention.

First, please refer to FIG. 6. At the beginning of the process, a substrate 100 is provided as the basis for the LDMOS device of the present invention. The material of the substrate 100 is preferably a silicon substrate, such as a P-type doped (P−) silicon substrate. Next, a plurality of fins F are formed on the substrate 100. The fins F are spaced apart in parallel on the substrate 100 and extend in the same direction. The fins F may be formed by performing a photolithography process on the substrate 100, such as using a photoresist with fin pattern as an etching mask to perform an anisotropic dry etching process on the substrate 100, which may be reactive ion etching (RIE) or plasma etching process. The fins F formed in the two cross-sectional areas in this step will have the same height. After the fins F are formed, an ion implantation process can be performed to form the aforementioned P-well and N-type drift region in the fins F (not shown).

Please refer to FIG. 7. After the fins F are formed, a first photolithography process P1 is then performed to remove parts of the fins F in the cross-sectional area Y3-Y3′, so as to reduce the height of these fins F. The first photolithography process P1 may include forming a first photoresist 122 firstly on the cross-sectional area Y2-Y2′, and then performing an anisotropic dry etching on the cross-sectional area Y3-Y3′ that is not blocked by the first photoresist 122, so that the height of the fin F in this area is reduced. The descended fin F will form a recessed region R as shown in FIG. 2, with its recess depth substantially equal to the thickness t of the thick oxide layer 106 to be formed later. In this way, the fins F in the two cross-sectional areas have different heights. Through this step, the depth of descended fins F in the cross-sectional area Y3-Y3′ can be precisely controlled to determine the thickness of the thick oxide layer to be formed thereon later, which is one of the advantages of the present invention.

Please refer to FIG. 8. After the recessed region R is formed, a dielectric layer 124, such as a silicon oxide layer, is then formed on the fins F. The dielectric layer 124 covers entire fins F and fills the spaces therebetween. The dielectric layer 124 can be formed by depositing a dielectric material through a CVD process and then performing a CMP process. For the cross-sectional area Y3-Y3′, depending on the removal degree of the dielectric layer 124 in the CMP process, the height of the formed dielectric layer 124 may be equal to or higher than the height of the fins F on the cross-sectional area Y3-Y3′. The dielectric layers 124 will become shallow trench isolations later that isolates every fin F. In another aspect, for the cross-sectional area Y3-Y3′, in addition to function as a shallow trench isolation, since the height of the fins F at this area is relatively low, there will be a certain thickness of the dielectric layer 124 located on the top surfaces of the fins F after the step. This portion of the dielectric layer 124 serves as the thick oxide layer required for the LDMOS of the present invention, with its thickness precisely controlled in this step, which is one of the advantages of the present invention.

Please refer to FIG. 9. After the dielectric layer 124 is formed, a second photolithography process P2 is then performed to remove parts of the dielectric layer 124 in the cross-sectional area Y2-Y2′, so that the height of the dielectric layer 124 is reduced to form a shallow trench isolation 102 between and around the fins F. The second photolithography process P2 may include first forming a second photoresist 126 on the cross-sectional area Y3-Y3′, and then performing an anisotropic dry etching process on the cross-sectional area Y2-Y2′ that is not blocked by the second photoresist 126, such that the height of the dielectric layer 124 is reduced below the fins F, forming the shallow trench isolation 102. For the cross-sectional area Y3-Y3′, since it is covered by the second photoresist 126, the dielectric layer 124 on the cross-sectional area Y3-Y3′ is not affected by the second photolithography process P2. In this way, for this area, the dielectric layer 124 located between and around the fins F serves as a shallow trench isolation 102, with its height higher than the shallow trench isolation 102 in the cross-sectional area Y2-Y2′, while the portion of the dielectric layer 124 above the height of the top surface of the fins F serves as the thick oxide layer 106 of the LDMOS.

Please refer to FIG. 10. After the thick oxide layer 106 is formed, a gate dielectric layer 104 of the LDMOS device is then formed on the surfaces of the fins F in the cross-sectional area Y2-Y2′. The material of gate dielectric layer 104 may be silicon oxide (ex. in the case of polysilicon gate) or a high-k material (in the case of metal gate), which may be formed by reacting the silicon-based surfaces of the fins with oxygen, or by deposition methods like CVD. The gate dielectric layer 104 formed in this step may also be formed on the surface of the thick oxide layer 106 and integrated with the thick oxide layer 106. The gate dielectric layer 104 formed in the cross-sectional area Y2-Y2′ will be connected with the thick oxide layer 106 in the cross-sectional area Y3-Y3′, as shown in FIG. 2. It should be noted that if the previous CMP process grinds the thick oxide layer 106 on the cross-sectional area Y3-Y3′ to a height flush with the height of the fins F on the cross-sectional area Y2-Y2′, the height of the gate dielectric layer 104 formed on the cross-sectional area Y2-Y2′ in this step will be higher than the height of the thick oxide layer 106. In addition, in the replacement metal gate process, the gate dielectric layer 104 is formed after the polysilicon gate is removed.

Please refer to FIG. 11. After the gate dielectric layer 104 is formed, a gate G is formed on the gate dielectric layer 104 and the thick oxide layer 106. The material of the gate G can be polysilicon, which can be formed by first depositing a polysilicon material layer using LPCVD process, and then patterning the polysilicon material layer into gate patterns through a photolithography process. As can be seen from the figure, the gate G on the cross-sectional area Y2-Y2′ will extend into the space between the fins F to form a three-dimensional channel structure, while the gates G on the cross-sectional area Y3-Y3′ are all located on the thick oxide layer 106.

According to the structures and methods described in the aforementioned embodiments, it can be seen that by reducing the height of the fins in specific areas and simultaneously forming the thick oxide layer with a shallow trench isolation, the thickness of the formed thick oxide layer can be precisely and uniformly controlled in the process of reducing the height of the fins and in the process of depositing the shallow trench isolation, addressing the shortcomings caused by thermally oxidizing the fins to form the thick oxide layer in conventional skills, which is the novelty and non-obviousness of the present invention lie in.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A LDMOS, comprising:
a substrate with a plurality of fins spaced apart in a first direction and extending in a second direction, wherein each fin is provided with a recessed region;
a shallow trench isolation surrounding said fins, wherein said shallow trench isolation located on said recessed regions forms a thick oxide layer;
a gate extending over said fins in said first direction, and two sides of said gate in said second direction are a first side and a second side respectively, wherein said thick oxide layer is close to said second side, and said gate partially overlaps said thick oxide layer on each of said fins in a direction vertical to said substrate; and
a source and a drain at said first side and said second side respectively in each of said fins, wherein said thick oxide layer extends from said second side of said gate to said drain.

2. The LDMOS of claim 1, further comprising a P-well in each of said fins close to said first side.

3. The LDMOS of claim 1, further comprising an N-type drift region in each of said fins close to said second side.

4. The LDMOS of claim 3, wherein a boundary of said N-type drift region is under said thick oxide layer.

5. The LDMOS of claim 1, further comprising a base in each of said fins outside said source.

6. The LDMOS of claim 5, further comprising a source epitaxial layer and a base epitaxial layer on each of said fins at said first side, said source epitaxial layer is between said gate and said base epitaxial layer, said source is in said source epitaxial layer, and said base is in said base epitaxial layer.

7. The LDMOS of claim 1, further comprising a drain epitaxial layer at said second side in each of said fins, said thick oxide layer is between said gate and said drain epitaxial layer, and said drain is in said drain epitaxial layer.

8. The LDMOS of claim 1, further comprising a gate oxide layer between said gate and said fins, and said gate oxide layer is directly connected with said thick oxide layer.

9. The LDMOS of claim 8, wherein a height of a top surface of said gate oxide layer is higher than a height of a top surface of said thick oxide layer.

10. The LDMOS of claim 8, wherein a height of a top surface of said gate oxide layer is lower than a height of a top surface of said thick oxide layer.

11. The LDMOS of claim 8, wherein a top surface of said gate oxide layer is flush with a top surface of said thick oxide layer.

12. The LDMOS of claim 8, further comprising an N-type drift region in each of said fins close to said second side, wherein a boundary of said N-type drift region is under said gate oxide layer.

13. The LDMOS of claim 1, wherein said gate is made of polysilicon or metal.

14. A method of manufacturing a LDMOS, comprising:
providing a substrate with a plurality of fins spaced apart in a first direction and extending in a second direction;
performing a first photolithography process to reduce a height of said fins in a recessed region;
forming a dielectric layer on said fins, wherein said dielectric layer on said fins in said recessed region forms a thick oxide layer;
performing a second photolithography process to reduce a height of said dielectric layer not located in said recessed region, so that said dielectric layer becomes a shallow trench isolation, and said fins not located in said recessed area protrude from said shallow trench isolation;
forming a gate extending over said fins in said first direction, wherein both sides of said gate in said second direction are a first side and a second side respectively, wherein said thick oxide layer is close to said second side, and said gate partially overlaps said thick oxide layer on each of said fins in a direction vertical to said substrate; and
forming a source and a drain respectively at said first side and said second side in each of said fins.

15. The method of manufacturing a LDMOS of claim 14, further comprising forming P-wells and N-type drift regions in said fins, wherein said P-wells are close to said first side, and said N-type drift regions are close to said second side.

16. The method of manufacturing a LDMOS of claim 14, further comprising forming a base in each of said fins outside said source.

17. The method of manufacturing a LDMOS of claim 16, further comprising forming a source epitaxial layer and a base epitaxial layer on each of said fins on said first side, said source epitaxial layer is between said gate and said base epitaxial layer, said source is formed in said source epitaxial layer, and said base is formed in said base epitaxial layer.

18. The method of manufacturing a LDMOS of claim 14, further comprising forming a drain epitaxial layer in each of said fins at said second side, said thick oxide layer is between said gate and said drain epitaxial layer, and said drain is formed in said drain epitaxial layer.

19. The method of manufacturing a LDMOS of claim 14, further comprising forming a gate oxide layer on surfaces of said fins before forming said gate, and said gate oxide layer is directly connected with said thick oxide layer.
